(19) United States
(12) Patent Application Publication
(10) Pub. No.: US 2010/0078727 A1
(43) Pub. Date: Apr. 1, 2010

(54) eFuse and Resistor Structures and Method for Forming Same in Active Region

(76) Inventors: Byoung W. Min, Hopewell Junction, NY (US); Satya N. Chakravarti, Hopewell Junction, NY (US)

Correspondence Address: HAMILTON & TERRILE, LLP - FREESCALE, P.O. BOX 203518, AUSTIN, TX, 78720, US

(21) Appl. No.: 12/243,313

(22) Filed: Oct. 1, 2008

(51) Int. Cl. H01L 27/092; H01L 21/8234; H01L 21/44

(52) U.S. Cl. 257/369; 438/238; 438/601; 257/E27.062; 257/E21.616; 257/E21.476

(57) ABSTRACT

A semiconductor fabrication process and apparatus are provided for forming passive devices, such as a fuse (93) or resistor (95), in an active substrate region (103) by using heavy ion implantation (30) and annealing (40) to selectively form polycrystalline structures (42, 44) from a monocrystalline active layer (103), while retaining the single crystalline regions in the active layer (103) for use in forming active devices, such as NMOS and/or PMOS transistors (94). As disclosed, fuse structures (93) may be fabricated by forming silicide (90) in an upper region of the polycrystalline structure (42), while resistor structures (95) may be simultaneously formed from polycrystalline structure (44) which is selectively masked during silicide formation.

### BACKGROUND OF THE INVENTION

1. Field of the Invention

The present invention is directed in general to the field of semiconductor fabrication and integrated circuits. In one aspect, the present invention relates to eFuse and resistor structures fabricated in an active region layer.

2. Description of the Related Art

Semiconductor devices have conventionally been fabricated by forming active devices (such as NMOS and PMOS transistors) over an active region of the semiconductor substrate by patterning polysilicon layers over a single crystal substrate to defined gate electrodes, and then implanting device features (e.g., source/drain regions) around the gate electrodes. With such conventionally formed devices, passive devices (such as capacitors or resistors) are separately formed over a non-active region, such as a field oxide region, by depositing a polysilicon layer over the field oxide which is then patterned and doped as needed to obtain the desired characteristics for the passive device. However, as semiconductor devices are scaled down, the height of the polysilicon gate is reduced in order to obtain better patterning resolution, which means that there is less polysilicon available for use in forming the passive devices. This problem is exacerbated with newer process technologies which form metal gate electrodes over high-k dielectric layers using very thin polysilicon layers, making it even more difficult to efficiently form passive devices from the very thin polysilicon layers. For example, the thickness variation in thin polysilicon layers creates design tolerance problems for resistor applications. And with eFuse applications, there are significant problems created if the thin poly layer is fully silicided, thereby limiting silicide migration. Another drawback with conventional processes is that additional mask steps are required to form the passive devices with a separate polysilicon layer, resulting in increased process complexity.

To avoid processing complexity, other device fabrication processes have formed eFuse structures with a silicided, doped monocrystalline silicon layer. While this approach results in an eFuse structure that can act as an active device when the fuse is programmed (e.g., when the silicide is moved or broken under electrical bias), the resulting eFuse structure has performance limitations because of the difficulty of electro-migrating silicide through the single crystalline silicon layer structure.

Accordingly, there is a need for improved semiconductor processes and devices to overcome the problems in the art, such as outlined above. Further limitations and disadvantages of conventional processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings, in which:

FIG. 1 illustrates a partial cross-sectional view of a semiconductor wafer structure in which a single crystal semiconductor layer and buried oxide layer are formed over a semiconductor substrate;

FIG. 2 illustrates processing subsequent to FIG. 1 after a patterned implant mask is formed over the single crystal semiconductor layer;

FIG. 3 illustrates processing subsequent to FIG. 2 after unmasked portions of the single crystal semiconductor layer are amorphized by implantation with a heavy ion species;

FIG. 4 illustrates processing subsequent to FIG. 3 after the semiconductor wafer structure is heated with an anneal process;

FIG. 5 illustrates processing subsequent to FIG. 4 after shallow trench isolation regions are formed to delineate different regions in the active device area of the semiconductor wafer structure;

FIG. 6 illustrates processing subsequent to FIG. 5 after a transistor device is formed in a transistor region of the active device area;

FIG. 7 illustrates processing subsequent to FIG. 6 after a second patterned mask is formed over a resistor region of the active device area;

FIG. 8 illustrates processing subsequent to FIG. 7 after a metal layer is formed over the semiconductor wafer structure;

FIG. 9 illustrates processing subsequent to FIG. 8 after silicide layers are formed in exposed polycrystalline semiconductor layers of the semiconductor wafer structure not protected by the second patterned mask;

FIG. 10 illustrates processing subsequent to FIG. 9 after a pre-metal low-k dielectric layer is formed over the semiconductor wafer structure to include contact electrodes for any eFuse or resistor structures; and

FIG. 11 illustrates a partial cross-sectional view of a semiconductor wafer structure in which eFuse and/or resistor structures are formed by amorphizing a single crystal SOI active layer in accordance with one or more second example embodiments where the transistor region is formed by epitaxially growing a semiconductor layer from the bulk semiconductor substrate.

It will be appreciated that for simplicity and clarity of illustration, elements illustrated in the drawings have not necessarily been drawn to scale. For example, the dimensions of some of the elements are exaggerated relative to other elements for purposes of promoting and improving clarity and understanding. Further, where considered appropriate, reference numerals have been repeated among the drawings to represent corresponding or analogous elements.

### DETAILED DESCRIPTION

A semiconductor fabrication process and resulting integrated circuit are described for manufacturing passive devices, such as fuse, eFuse or resistor structures, in an active substrate region of a integrated circuit device by using heavy ion implantation and anneal processes to selectively form amorphous or polycrystalline regions in a monocrystalline active layer, while retaining the single crystalline regions in the active layer for use in forming active devices, such as NMOS and/or PMOS transistors. For example, the crystalline structure of a monocrystalline silicon layer can be changed to have a polycrystalline structure by selectively implanting heavy ion species (e.g., Xe, Ge, Ar, In, Sb, As, P, BF₂, Si, and/or other amorphizing ions) into the monocrystalline silicon layer and then annealing the implanted region while other active device areas are protected to maintain the original single crystalline structure. Selected embodiments of the present invention may use patterned mask formation, implantation and annealing processes within an existing CMOS integration to efficiently form passive devices, thereby eliminating the requirement for a separate mask step and reducing the overall process complexity for integrating passive devices with metal gate/high-k dielectric transistor devices.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional drawings of a semiconductor device that are not necessarily drawn to scale and that do not include every device feature or geometry in order to avoid limiting or obscuring the present invention. Such descriptions and representations are used by those skilled in the art to describe and convey the substance of their work to others skilled in the art. In addition, although specific example materials are described herein, those skilled in the art will recognize that other materials with similar properties can be substituted without loss of function. It is also noted that, throughout this detailed description, certain materials will be formed and removed to fabricate the semiconductor structure. Where the specific procedures for forming or removing such materials are not detailed below, conventional techniques to one skilled in the art for growing, depositing, removing or otherwise forming such layers at appropriate thicknesses shall be intended. Such details are well known and not considered necessary to teach one skilled in the art of how to make or use the present invention.

Referring now to FIG. 1, there is shown a partial cross-sectional view of a semiconductor wafer structure 1 in which a single crystal semiconductor layer 103 and buried oxide layer 102 are formed over a semiconductor substrate 101 that has a predetermined crystallographic orientation. Depending on the type of transistor device being fabricated, the semiconductor layer 101 may be formed from any semiconductor material, including, for example, Si, SiC, SiGe, SiGeC, Ge, GaAs, InAs, InP as well as other III/V or II/VI compound semiconductors or any combination thereof. The wafer structure 1 also includes an insulator layer 102 formed on the semiconductor substrate 101 which will ultimately be used to form the buried oxide (BOX) layer for silicon-on-insulator devices. In addition, a second semiconductor layer 103 is formed over the insulator layer 102 from a semiconductor material having single crystallographic orientation which may be the same as or different from the crystallographic orientation of the semiconductor layer 103. Depending on the type of transistor device being fabricated, the second semiconductor layer 103 may be formed from any semiconductor material, including, for example, Si, SiC, SiGe, SiGeC, Ge, GaAs, InAs, InP as well as other III/V or II/VI compound semiconductors or any combination thereof, and may be formed as a strained semiconductor layer. As will be understood by those skilled in the art, a single crystal semiconductor layer (such as monocrystalline silicon) has a single and continuous crystal lattice structure that is substantially continuous and unbroken with no grain boundaries and with practically zero defects or impurities, at least as initially formed. The wafer structure 1 is commonly known as semiconductor on insulator (SOI) structure, and it will be appreciated that any of a variety of fabrication sequences can be used to form the semiconductor wafer structure 1. Though not explicitly shown, those skilled in the art will appreciate that the semiconductor wafer structure 1 may be formed by bonding a donor wafer to a handle wafer. With this technique, a handle wafer is processed to include the substrate layer 101 as the bulk portion of a stack including at least part of the dielectric layer 102 formed on the substrate layer 101. In addition, a donor wafer is processed to form a stack including at least part of the dielectric layer 102 and the semiconductor layer 103. By bonding the dielectric layer 102 portion of a donor wafer to the dielectric layer portion of the handling wafer, the semiconductor wafer structure 1 is formed.

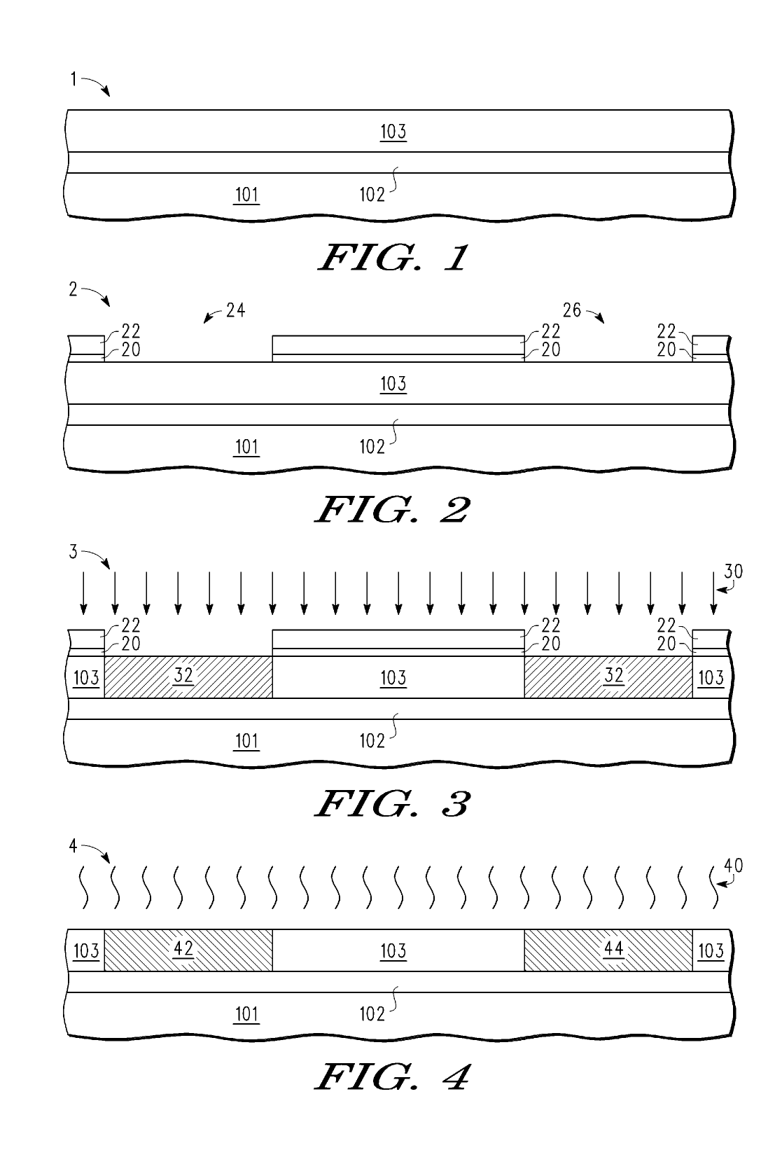

Turning now to FIG. 2, there is illustrated processing of a semiconductor wafer structure 2 subsequent to FIG. 1 after a patterned implant mask 20, 22 is formed over the single crystal semiconductor layer 103. The implant mask may be formed by growing or depositing a first oxide layer 20 (e.g., pad oxide) and a nitride mask layer 22 over the single crystal semiconductor layer 103, and then selectively etching the layers 20, 22 to define mask openings 24, 26 using any desired patterning and etch sequence, including but not limited to depositing, patterning and etching a photoresist or hard mask layer. For example, portions of the deposited nitride layer 22 may be etched or removed using a mask or photoresist (not shown) to remove an exposed portion of the nitride layer 22, thereby forming opening to expose the pad oxide layer 20. The pattern transfer and etching of the mask layer may use one or more etching steps to selectively remove the unprotected portions of the oxide layer 20, including a dry etching process such as reactive-ion etching, ion beam etching, plasma etching or laser etching, a wet etching process wherein a chemical etchant is employed or any combination thereof. The openings 24, 26 are used to define and differentiate passive device regions in a monocrystalline active layer from the active device regions which are covered by the mask 20, 22 and subsequently used to form active devices, such as NMOS and/or PMOS transistors. For example, at least part of the second semiconductor layer 103 exposed by the opening 24 defines a first passive device region for a first type of passive device, such as an eFuse, while at least part of the second semiconductor layer 103 exposed by the opening 26 defines a second passive device region for a second type of passive device, such as a resistor.

FIG. 3 illustrates processing of a semiconductor wafer structure 3 subsequent to FIG. 2 after unmasked portions 32 of the single crystal semiconductor layer 103 are amorphized by implantation with a heavy ion species 30. As will be understood by those skilled in the art, an amorphous semiconductor layer is the opposite of a single crystal structure in that the atomic position is limited to short range order only so that there is no discernible crystalline structure. With the implant mask 20, 22 in place, implant regions 32 in the single crystal semiconductor layer 103 are implanted with a neutral, amorphizing implant species 30, such as Xe, Ge, Ar, In, Sb, As, P, BF₂, Si, or another amorphizing heavy ion species. One advantage of implanting a heavy ion species into the single crystal semiconductor layer 103 is that the implanted regions 32 are amorphized where passive devices, such as poly resistors and/or silicided effuses, will subsequently be formed. Another advantage of implanting neutral or inert heavy ions is that the implanted regions 32 of the semiconductor layer 103 remain undoped (or no additional doping is added to the original doping level of the layer 103). In selected embodiments, the implanted regions 32 may be counter-doped with an additional implant or doping process to make the implanted regions 32 undoped or substantially undoped, or to provide a predetermined level of doping to control a device characteristic, such as the conductance of a resistor. The implantation of heavy ions to amorphize the implanted regions 32 also helps form polycrystalline regions 32 which helps the electro-migration of silicide in polysilicon based eFuse by creating thermal and diffusion gradients during programming. Depending on the implant conditions, the concentration profile of the implanted species 30 will create implant regions 32 at a predetermined depth in the semiconductor layer 103, though as shown in FIG. 3, the amorphized structure of the implanted regions 32 extends all the way to the buried oxide layer 102. In a selected embodiment, a heavy implant species 30, such as xenon, is implanted with an implant energy of approximately 30 keV and a dosage of approximately 1E15 cm⁻², though other implant energies and dosages may be used as desired, depending on the thickness of the semiconductor layer 103. Of course, other implant materials 30 may be used as an amorphizing ion, such as argon, germanium, etc. It should be noted that the heavy ion implantation step may, in various embodiments of the present invention, be moved in the fabrication sequence to be closer to or part of the source/drain formation.

Because the implanted regions 32 are amorphous, they have a special properties (e.g., in regard to diffusivity) that may not be suitable for use in fabricating passive devices. Accordingly, the amorphous phase of the implanted regions is converted into a polycrystalline phase by applying an anneal process, as shown in FIG. 4 which illustrates processing of a semiconductor wafer structure 4 subsequent to FIG. 3 after one or more thermal anneal processes 40 are applied to anneal the implanted regions 42, 44 in accordance with selected embodiments of the present invention. As will be understood by those skilled in the art, a polycrystalline semiconductor structure has a crystalline structure that is between the single crystal and amorphous structures in that the polycrystalline material has a number of smaller, randomly oriented crystals or crystallites. While the polycrystalline regions 42, 44 are depicted in FIG. 4 as being the same size as the corresponding implanted regions 32 (shown in FIG. 3), the anneal process 40 may physically disperse or drive the implanted species. In a selected embodiment, the anneal process 40 is applied as a rapid thermal anneal (RTA) process to heat the semiconductor wafer structure 4 to a relatively moderate temperature for a short time (e.g., approximately 700-1100° C. for between 10-60 seconds), though other temperatures and ramp times may be used, including but not limited to longer anneal times at higher or lower temperatures, with or without temperature ramps. In selected embodiments, the implanted regions 32 are annealed in nitrogen using an RTA process 400 that does not use very high temperatures (e.g., 1100-1200° C.), though other gases (such as helium, argon, oxygen, etc) may also be used. In addition, other anneal processes may be used, including adding a spike anneal (e.g., 1000-1100° C. for approximately less than one second) or adjusting the parameters of the anneal process based on what materials, thicknesses and implant species are used to form the implanted regions 32 in the semiconductor layer 103. Also, when other amorphizing ion species are used, the temperatures and other anneal conditions may be adjusted appropriately. Whichever anneal process 40 is applied, the thermal cycle is controlled so that the amorphous structure of the implanted regions 32 is changed into active regions 42, 44 that have a polycrystalline structure or at least a semiconductor region which has abundant defects. If the thermal cycle does not require a very high temperature, the anneal process 40 may be moved later in the process, such as after the formation of the shallow trench isolation regions (described below).

FIG. 5 illustrates processing of a semiconductor wafer structure 5 subsequent to FIG. 4 after shallow trench isolation regions 50 are formed to delineate different regions in the active device area of the semiconductor wafer structure, and in particular, to electrically isolate the passive device area(s) 51, 53 from the active device area(s) 52 formed in the in the active layer 103. As will be appreciated, isolation structures 50 may be formed using any desired technique, such as selectively etching one or more openings in the second semiconductor layer 103 and/or implant regions 42, 44 down to the buried oxide layer 102 using a patterned mask or photoresist layer (not shown), depositing a dielectric layer (e.g., oxide) to fill the opening(s), and then polishing the deposited dielectric layer until planarized with the remaining second semiconductor layer 103 and/or implant regions 42, 44. Any remaining unetched portions of the patterned mask or photoresist layer(s) are stripped.

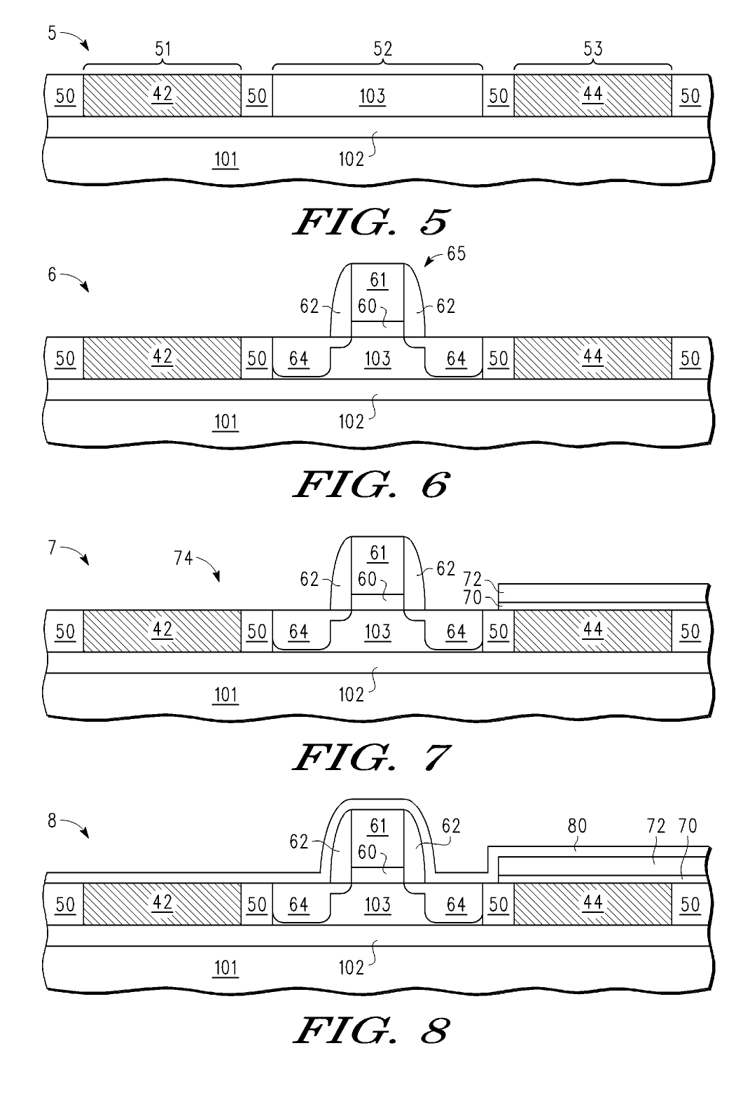

FIG. 6 illustrates processing of a semiconductor wafer structure 6 subsequent to FIG. 5 after a transistor device 65 (e.g., an NMOS and/or PMOS transistor) is formed in a transistor region 52 of the active device area. As illustrated, the transistor 65 includes one or more gate dielectric layers 60, a conductive gate electrode 61 overlying the gate dielectric 60, sidewall implant spacers 62 formed from one or more dielectric layers on the sidewalls of gate electrode 61, and source/drain regions 64 formed in the active layer 103. Gate dielectric layer(s) 60 may be formed by depositing or growing an insulator or high-k dielectric (e.g., silicon dioxide, oxynitride, metal-oxide, nitride, etc.) over the single crystal semiconductor layer 103 using chemical vapor deposition (CVD), plasma-enhanced chemical vapor deposition (PECVD), physical vapor deposition (PVD), atomic layer deposition (ALD), thermal oxidation, or any combination(s) of the above to a predetermined final thickness in the range of 0.1-10 nanometers, though other thicknesses may be used. Conductive gate electrode(s) 61 may be a heavily doped (n+) polysilicon gate electrode, a metal gate electrode, or a combination thereof that is formed using any desired deposition or sputtering process, such as CVD, PECVD, PVD, ALD, molecular beam deposition (MBD) or any combination(s) thereof to a predetermined final thickness in the range of 1-100 nanometers, though other thicknesses may be used. Sidewall implant spacers 62 may be formed from an offset or spacer liner layer (e.g., a deposited or grown silicon oxide), alone or in combination with an extension spacer formed by depositing and anisotropically etching a layer of dielectric. Subsequent to forming at least the gate electrodes 61, lightly doped extension regions 64 may be formed by selectively masking the PMOS or NMOS areas as needed, and implanting dopant impurities into the exposed single crystal semiconductor layer 103, using the gate electrode(s) 61, alone or with an offset/spacer liner layer, as a implant mask to protect the MOS channel from implantation. In addition or in the alternative, heavily doped source/drain regions 64 may be formed by selectively masking the PMOS or NMOS areas as needed, and implanting dopant impurities into the exposed single crystal semiconductor layer 103, using the gate electrode(s) 61, alone or with an offset or spacer liner layer and/or implant spacer 62, as a implant mask to protect the channel from implantation. As described herein, any desired fabrication techniques may be used to grow, deposit, pattern, remove, etch or otherwise forming the various features of the transistor device 65.

To the extent that silicide is to be formed on active devices (e.g., NMOS and/or PMOS transistors) and/or passive devices (e.g., eFuse structures), it may be necessary to mask off regions of the wafer where silicide is not to be formed. To this end, FIG. 7 illustrates processing of a semiconductor wafer structure 7 subsequent to FIG. 6 after a second patterned mask 70, 72 is formed over a resistor region 53 of the active device area. For example, the implant mask may be formed by growing or depositing a first oxide layer 70 (e.g., pad oxide) and a nitride mask layer 72 over the semiconductor wafer structure 7, and then selectively etching the layers 70, 72 to define mask openings 74 over the intended silicide regions using any desired patterning and etch sequence, including but not limited to depositing, patterning and etching a photoresist or hard mask layer. For example, portions of the deposited nitride layer 72 may be etched or removed using a mask or photoresist (not shown) to remove an exposed portion of the nitride layer 72, which in turn is used as a mask to selectively remove the unprotected portions of the oxide layer 70, thereby exposing the passive device area(s) 51 and the active device area(s) 52.

With the intended silicide regions exposed, silicide regions are then formed using any desired silicide formation sequence, such as the example sequence of silicide formation depicted beginning with FIG. 8 which illustrates processing of a semiconductor wafer structure 8 subsequent to FIG. 7 after a conductive or metal layer 80 (e.g., cobalt or nickel) is formed over the semiconductor wafer structure. In an illustrative implementation, the metal layer 80 may be formed by depositing or sputtering one or more layers of conductive material (such as cobalt or nickel) to a thickness of approximately 50-200 Angstroms, though a thinner or thicker layer may also be used. Other conductive materials, such as nickel, may also be formed or sputtered. In one embodiment, the deposited metal layer 80 is comprised of a bottom metal layer such as cobalt and a top barrier layer such as TiN. As depicted, the deposited metal layer 80 covers the entirety of the semiconductor structure 7. Though not shown, any oxide liner layer on the unmasked semiconductor wafer structure 8 may be removed from the exposed polycrystalline regions 42, 44 and source/drain regions 64 prior to depositing the metal layer 80, though the timing and sequence of the source/drain formation may be varied.

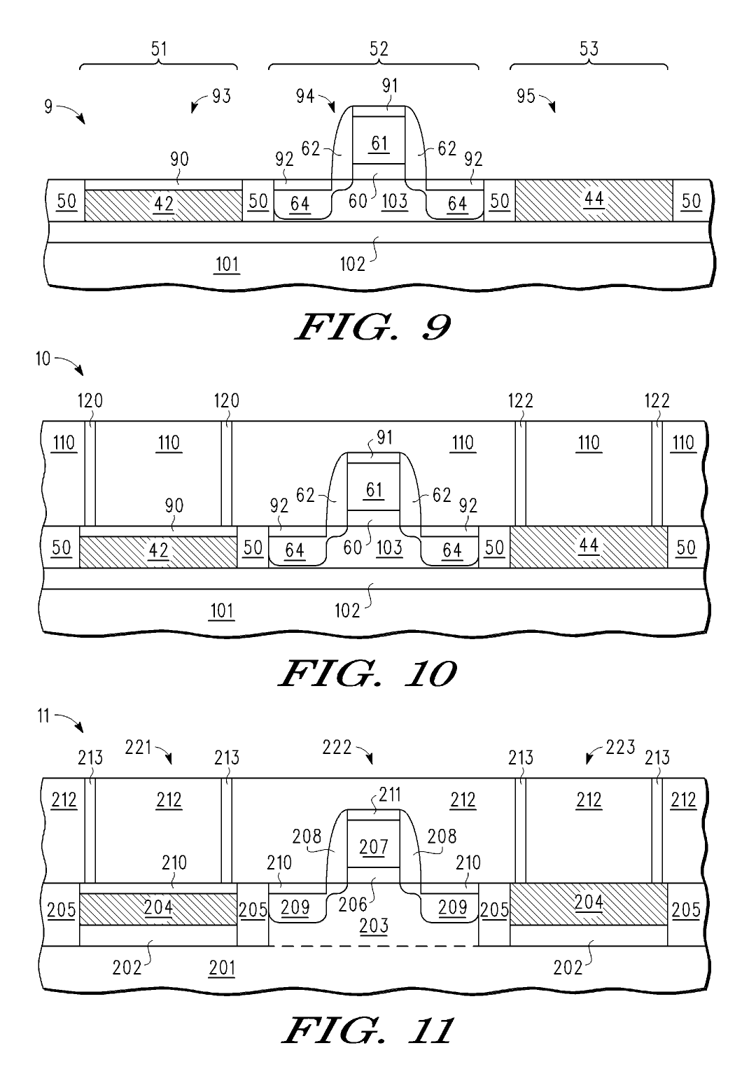

FIG. 9 illustrates processing of the semiconductor structure 9 subsequent to FIG. 8 after silicide layers 90-92 are formed in exposed polycrystalline semiconductor layers of the semiconductor wafer structure 9 and the second patterned mask 70, 72 has been removed or stripped. To form the silicided eFuse structures, the metal layer 80 reacts with at least the polysilicon structure 42 in the passive device area(s) 51 not protected by the second patterned mask 70, 72 to form a silicide layer 90. As will be appreciated, the same process can be used to form silicide regions 91, 92 on the top of conductive gate electrode 61 and source/drain regions 64, respectively. In an illustrative embodiment, the reaction of the metal layer 80 and the underlying polycrystalline semiconductor regions 42, 61 is promoted by performing an initial rapid thermal anneal step (e.g., 400-600° C.), followed by a Piranha clean step to remove the metal from the exposed surfaces of the underlying semiconductor regions 42, 61, 64, and then followed by a second rapid thermal anneal step (e.g., 650-850° C.). The timing and temperature of the initial rapid thermal anneal step are selected so that the metal layer 80 reacts with the exposed surfaces of the underlying semiconductor regions 42, 61, 64, but not with the sidewall spacers 62 or the isolation structures 50. As a result, the reacted silicide regions 90-92 may be formed after the initial rapid thermal anneal step on the exposed surfaces of the polycrystalline semiconductor regions 42, 61 and the source/drain regions 64. After the Piranha clean step, the timing and temperature of the second rapid thermal anneal step are selected so that the reacted silicide 90-92 is pushed into a low resistivity phase.

As shown in FIG. 9, the eFuse structure 93 includes a polycrystalline structure 42 that is formed by implanting and annealing the single crystal active semiconductor layer 103 of the SOI substrate. Though not shown in the cross-sectional profile, the polycrystalline structure 42 may be patterned into a strip, and may also be doped with one or more impurities before or after the patterning. In addition, at least an upper portion of the polycrystalline structure 42 is also silicided to form a silicided strip or region 90 over the unreacted portion of the polycrystalline structure 42. The overlying silicide region 90 allows the fuse to act as a conductor in its unprogrammed state, and is able to readily electro-migrate over the underlying polycrystalline structure 42 when the eFuse structure 93 is programmed (and the silicide is moved or broken). FIG. 9 also shows that the resistor structure 95 includes a polycrystalline structure 44 that is formed by implanting and annealing the single crystal active semiconductor layer 103 of the SOI substrate. Though not shown in the cross-sectional profile, the polycrystalline structure 44 may be patterned into a strip, and may also be doped with one or more impurities before or after the patterning to control the resistivity of the resistor structure 95. At this stage of the process, the polycrystalline structure 42 formed in the eFuse device area 51 is sufficiently thick that there is much less chance of having an eFuse malfunction by having all of the polycrystalline material consumed by the silicide formation process, as occurs with conventional eFuse fabrication processes. In addition, silicon migration is easier to achieve over the relatively thicker polycrystalline structure 42 than over the thinner polysilicon eFuse layers or monocrystalline layers formed with conventional processes.

To complete the fabrication of the resistor and eFuse structures formed in the active layer, backend processing steps are used to form metal contacts and multiple levels of interconnect for electrically coupling the resistor and eFuse structures to the outside world. For example, FIG. 10 illustrates the beginning of an example sequence for processing the semiconductor structure 10 subsequent to FIG. 9 after a pre-metal low-k dielectric layer 110 is formed over the semiconductor wafer structure 10 to include contact electrodes 120, 122 for any eFuse or resistor structures, respectively. In particular, after forming the passive and active device components 93-95, the components are electrically isolated with a BEOL process that begins by blanket depositing at least a layer of low-k dielectric pre-metal material 110 over the device components 93-95 by CVD, PECVD, PVD, ALD, or any combination thereof to a thickness of approximately 400-1000 nanometers, though other thicknesses may also be used. In selected embodiments, the deposited low-k dielectric pre-metal layer 110 is planarized or polished into a planarized dielectric layer 110, such as by using a chemical mechanical polishing step. Subsequently, contact hole openings are formed in the planarized dielectric layer 110 above selected contact regions over the eFuse structure(s) 93 and/or resistor structure(s) 95 in the active layer, as well as over the source/drain regions 64 and gate electrode 61. Any desired contact etch process may be used to form the contact hole openings, such as applying and patterning a layer of photoresist (not shown) as an etch mask to expose the dielectric layer 110 at the contact hole locations, and then applying the appropriate etchant processes to etch the contact holes. For example, an etch process, such as an Argon, CHF₃, or CF₄ chemistry that is used to etch carbon-doped oxide film, may be used to etch through the exposed portion of the low-k dielectric layer 110. Once the contact hole openings are formed, a layer of contact metal material 120, 122 is formed to fill the contact hole openings, such as be depositing one or more conductive materials or layers 120, 122 (such as tungsten, copper and/or a barrier layer) to fill the contact hole openings to form a contact plug 120, 122. This may be accomplished using any desired technique to fill the contact holes, such as depositing one or more layers of contact metal, such as tungsten. Finally, a chemical mechanical polish (CMP) step may be applied to remove any excess conductive material 120, 122 from above the contact hole opening. As shown in FIG. 10, a CMP process is used to polish the contact metal layer 120, 122 until it is etched back and substantially co-planar with the pre-metal dielectric layer 110. By using a timed CMP process, the excess metal is removed, leaving only the metal plugs 120, 122 in the contact hole openings.

As shown in FIG. 10, the resistor structure 95 produced by the foregoing methodology includes a polycrystalline active silicon layer 44 on a first insulator layer 102, additional insulator layers 50, 110 formed on and around the polycrystalline active silicon layer 44, and electrical contacts 122 that extend through the second insulator layer 110 and connect to ends of the strip of polycrystalline active silicon layer 44. In addition, the eFuse structure 93 produced by the foregoing methodology includes a polycrystalline active silicon layer 42 on a first insulator layer 102, a silicide layer 90 on the polycrystalline active silicon layer 42, additional insulator layers 50, 110 formed on and around the silicide layer 90, and electrical contacts 120 that extend through the second insulator layer 110 and connect to ends of the strip of polycrystalline active silicon layer 42. In selected embodiments, the silicide layer 90 and the polycrystalline active silicon layer 42 in an unblown state form a substantially conductive eFuse structure. However, when sufficient current passes through the eFuse structure, the silicide layer 90 melts and electromigrates during programming to shift position, thereby forming a substantially non-conductive member. As will be appreciated, the amount of current necessary to program the fuse will vary depending upon the size of the fuse, the material used to form the silicide 90, and other factors. By using polycrystalline silicon that is formed by implanting and annealing the active monocrystalline layer instead of using monocrystalline silicon, the eFuse structure 93 and resistor structure 95 are formed in the same active layer as the transistors 94, thereby eliminating the need for additional masking steps (that would otherwise be used to form a separate polysilicon layer) and improving the electromigration of silicide during eFuse programming.

As will be appreciated, the processing sequence used to fabricate passive devices from polycrystalline structures formed in a monocrystalline active semiconductor layer—namely heavy ion implantation and annealing—can be implemented in a variety of different CMOS integration processes. Thus, not only can passive devices be formed in the active layer of an SOI structure (such as described above), the disclosed processing sequence can also be used to fabricate passive devices in other types of substrate structures, such as bulk silicon devices or hybrid substrate devices in which different substrates having different surface orientations or formed on a single wafer structure. For example, FIG. 11 illustrates a partial cross-sectional view of a hybrid semiconductor wafer structure 11. As depicted, an eFuse structure 221 and a resistor structure 223 are formed by amorphizing a single crystal active layer and then annealing the implanted amorphous layer to form polycrystalline structures 204, while a transistor device 222 is formed over an bulk or epitaxially grown substrate layer 203. In selected embodiments employing an SOI substrate structure, those skilled in the art will appreciate that an upper semiconductor layer (not shown) may be formed over and isolated from an underlying substrate 201 by a buried oxide layer 202, and then selectively implanted with heavy ions (e.g., using an implant mask) and annealed to form the polycrystalline structures 204 which are electrically isolated by shallow trench isolation regions 205 from a second semiconductor layer 203 which is epitaxially grown from the underlying substrate 201. In other embodiments employing a bulk substrate structure, those skilled in the art will appreciate that passive device area(s) of an upper region 203 of the substrate 201 may be selectively implanted with heavy ions (e.g., using an implant mask) and annealed to form the polycrystalline structures 204 which are electrically isolated by shallow trench isolation regions 205 and a buried oxide layer 202 that is formed by implanting oxygen below the polycrystalline structures 204 and then performing a high temperature anneal prior to forming the STI regions 205.

Regardless of the type of substrate structure used, the active devices (e.g., NMOS and/or PMOS transistors 222) may be formed in a active area by forming one or more gate dielectric layers 206, a conductive gate electrode 207 overlying the gate dielectric 206, sidewall implant spacers 208 formed from one or more dielectric layers on the sidewalls of gate electrode 207, and source/drain regions 209 formed in the active layer 203. Thus formed, the active and/or passive devices (e.g., eFuse structures 221) formed from the polycrystalline active layer 204 may be selectively silicided to form silicide regions 210-211 by depositing and annealing a metal layer (not shown) on the exposed surfaces of the polycrystalline semiconductor regions 204, 207 and the source/drain regions 209. Additional backend processing is used to connect the passive devices 221, 223 by forming contacts 212 in the pre-metal dielectric layer 211.

It will be appreciated that additional processing steps will be used to complete the fabrication of the semiconductor structures into functioning transistors or devices. As examples, one or more sacrificial oxide formation, stripping, isolation region formation, well region formation, extension implant, halo implant, spacer formation, source/drain implant, heat drive or anneal steps, and polishing steps may be performed, along with conventional backend processing (not depicted), typically including formation of multiple levels of interconnect that are used to connect the transistors in a desired manner to achieve the desired functionality. Thus, the specific sequence of steps used to complete the fabrication of the semiconductor structures may vary, depending on the process and/or design requirements.

By now, it should be appreciated that there has been provided herein a semiconductor fabrication process for forming passive and active devices in an active layer. In the disclosed methodology, a semiconductor substrate wafer is provided that includes an active semiconductor layer which initially has a single crystal structure. In selected embodiments, the semiconductor substrate wafer is provided as a bulk semiconductor substrate or a semiconductor-on-insulator (SOI) substrate structure in which the active semiconductor layer is formed over and insulated from an underlying semiconductor substrate in at least the second region. A first region of the active semiconductor layer is then amorphized where the passive devices are to be formed without changing the single crystal structure of the active semiconductor layer where active devices are to be formed. In various embodiments, the amorphization is implemented by applying a preamorphizing implant into the first region to create an amorphized region, such as by selectively implanting heavy ions (e.g., Xe, Ge, Ar, In, Sb, As, P, BF2, Si, or the like) into the first region of the active semiconductor layer using an implant mask. The amorphized first region is then annealed to form polycrystalline structures in the active semiconductor layer, thereby rendering the amorphized region into a polycrystalline region. Having thus prepared the active semiconductor layer, passive devices (e.g., electronic fuses and/or resistors) are formed from the polycrystalline structures in the first region, while active devices are formed from the single crystal structure in the second region. Examples of passive devices include fuse or eFuse structures that are formed by silicidation of an upper region of the polycrystalline structures in the first region of the active semiconductor layer, or resistor structures that are formed from the polycrystalline structures in the first region of the active semiconductor layer. To form fuse and resistor structures, a silicide layer may be formed in an upper region of a first polycrystalline structure in the first region of the active semiconductor layer without forming silicide over a second polycrystalline structure in the first region of the active semiconductor layer that is used to form the resistor. Examples of active devices include MOS gate structures (e.g., high-k gate dielectrics with metal gate electrodes) that are formed over the second region and used to implant source/drain regions into the single crystal structure of the active semiconductor layer around the MOS gate structures. Before or after the first regions are annealed, one or more dielectric layers may be formed to electrically isolate the passive devices from the active devices.

In another form, there is provided method for forming a fuse in an active semiconductor layer. As a preliminary step, a semiconductor substrate wafer is selectively masked to expose a first region of an active semiconductor layer having a single crystal structure, such as by patterning a photoresist layer over the active semiconductor region to expose the first region and to protect a second region of the active semiconductor layer where one or more active devices are to be formed. The first region of the active semiconductor layer may then be implanted to create an amorphous structure in the first region, such as by selectively implanting heavy ions into the first region of the active semiconductor layer. Subsequently, the amorphous structure in the first region may be rendered into a polycrystalline structure, such as by annealing the active semiconductor layer to form one or more polycrystalline structures in the first region of the active semiconductor layer. Finally, a silicide layer is formed in a top portion of the first region while retaining the polycrystalline crystal structure in a lower portion of the first region. The silicide layers may be formed by selectively forming one or more layers of conductive material over at least the one or more polycrystalline structures, and then heating the semiconductor substrate wafer to react the one or more layers of conductive material with a top portion of the polycrystalline structures, thereby forming a silicide layer.

In yet another form, there is provided a CMOS integrated circuit and methodology for fabricating same. As formed, the CMOS integrated circuit includes a semiconductor substrate with an active semiconductor layer that has a first region with a single crystal structure and a second region with a polycrystalline structure that is formed by selectively amorphizing the second region and then annealing the second region to form the polycrystalline structure. The CMOS integrated circuit also includes one or more NMOS and PMOS transistor devices formed in the a single crystal structure of the first region, and one or more passive devices formed in the polycrystalline structure of the second region. In the example embodiments described herein, the passive devices include a resistor structure or a silicided fuse structure formed in the polycrystalline structure of the second region.

Although the described exemplary embodiments disclosed herein are directed to various semiconductor device structures and methods for making same, the present invention is not necessarily limited to the example embodiments which illustrate inventive aspects of the present invention that are applicable to a wide variety of semiconductor processes and/or devices. Thus, the particular embodiments disclosed above are illustrative only and should not be taken as limitations upon the present invention, as the invention may be modified and practiced in different but equivalent manners apparent to those skilled in the art having the benefit of the teachings herein. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A semiconductor fabrication process, comprising:
providing a semiconductor substrate wafer comprising an active semiconductor layer which initially has a single crystal structure;
amorphizing a first region of the active semiconductor layer where one or more passive devices are to be formed without changing the single crystal structure of the active semiconductor layer in a second region where one or more active devices are to be formed;
annealing the active semiconductor layer to form one or more polycrystalline structures in the first region of the active semiconductor layer;
forming one or more passive devices from the one or more polycrystalline structures in the first region of the active semiconductor layer; and
forming one or more active devices from the single crystal structure of the active semiconductor layer in the second region.

2. The process of claim 1, where providing a semiconductor substrate wafer comprises providing a semiconductor-on-insulator (SOI) structure in which the active semiconductor layer is located over and insulated from an underlying semiconductor substrate in at least the second region.

3. The process of claim 1, where amorphizing the first region comprises selectively implanting heavy ions into the first region of the active semiconductor layer using an implant mask.

4. The process of claim 1, where amorphizing the first region comprises implanting the first region of the active semiconductor layer with Xe, Ge, Ar, In, Sb, As, P, BF₂, or Si.

5. The process of claim 1, where forming one or more passive devices comprises forming one or more fuse structures, wherein the forming one or more fuse structures comprises forming silicide in an upper region of the one or more polycrystalline structures in the first region of the active semiconductor layer.

6. The process of claim 1, where forming one or more passive devices comprises forming one a resistor structures from the one or more polycrystalline structures in the first region of the active semiconductor layer.

7. The process of claim 1, where forming one or more active devices comprises forming one or more MOS gate structures over the second region and implanting source/drain regions into the single crystal structure of the active semiconductor layer around at least the one or more MOS gate structures.

8. The process of claim 7, where the one or more MOS gate structures each comprise a high-k dielectric and a metal gate electrode.

9. The process of claim 1, further comprising forming one or more dielectric layers to electrically isolate the one or more passive devices from the one or more active devices.

10. The process of claim 1 where forming one or more passive devices comprises forming a fuse and resistor from the one or more polycrystalline structures in the first region of the active semiconductor layer.

11. The process of claim 10 forming a fuse comprises forming a silicide layer in an upper region of a first polycrystalline structure in the first region of the active semiconductor layer without forming silicide over a second polycrystalline structure in the first region of the active semiconductor layer that is used to form the resistor.

12. The process of claim 1 where providing a semiconductor substrate wafer comprises providing a semiconductor on insulator (SOI) substrate structure or a bulk semiconductor substrate.

13. The process of claim 1 where amorphizing a first region of the active semiconductor layer comprises applying a preamorphizing implant into the first region to create an amorphized region.

14. The process of claim 13 where annealing the active semiconductor layer renders the amorphized region into a polycrystalline region.

15. A method for forming a fuse in an active semiconductor layer, comprising:
selectively masking a semiconductor substrate wafer to expose a first region of an active semiconductor layer having a single crystal structure;
implanting the first region of the active semiconductor layer to create an amorphous structure in the first region;
rendering the amorphous structure in the first region into a polycrystalline structure; and
forming a silicide layer in a top portion of the first region while retaining the polycrystalline structure in a lower portion of the first region.

16. The method for forming a fuse of claim 15, where selectively masking the semiconductor substrate wafer comprises patterning a photoresist layer over the active semiconductor region to expose the first region and to protect a second region of the active semiconductor layer where one or more active devices are to be formed.

17. The method for forming a fuse of claim 15, where implanting the first region of the active semiconductor layer comprises selectively implanting heavy ions into the first region of the active semiconductor layer.

18. The method for forming a fuse of claim 15, where rendering the amorphous structure in the first region into a polycrystalline structure comprises annealing the active semiconductor layer to form one or more polycrystalline structures in the first region of the active semiconductor layer.

19. The method for forming a fuse of claim 18, where forming a silicide layer comprises:
selectively forming one or more layers of conductive material over at least the one or more polycrystalline structures; and
heating the semiconductor substrate wafer to react the one or more layers of conductive material with a top portion of the polycrystalline structures, thereby forming a silicide layer.

20. A CMOS integrated circuit, comprising:
a semiconductor substrate comprising an active semiconductor layer comprising a first region with a single crystal structure and a second region with a polycrystalline structure that is formed by selectively amorphizing the second region and then annealing the second region to form the polycrystalline structure;
one or more NMOS and PMOS transistor devices formed in the a single crystal structure of the first region; and
one or more passive devices formed in the polycrystalline structure of the second region.

21. The CMOS integrated circuit of claim 20, where the one or more passive devices comprise a resistor structure or a silicided fuse structure formed in the polycrystalline structure of the second region.
